(19) United States
(12) Patent Application Publication
(10) Pub. No.: US 2026/0082537 A1
(43) Pub. Date: Mar. 19, 2026

(54) METHOD FOR MANUFACTURING MEMORY DEVICE

(71) Applicant: NANYA TECHNOLOGY CORPORATION, New Taipei City (TW)

(72) Inventors: Chien-Ju WU, New Taipei City (TW); Tzu-Li TSENG, New Taipei City (TW)

(21) Appl. No.: 18/888,177

(22) Filed: Sep. 18, 2024

(51) Int. Cl. H10B 12/00

(52) U.S. Cl. CPC H10B 12/09

(57) ABSTRACT

A method for manufacturing a memory device includes forming a hard mask structure over a dielectric structure. The hard mask structure includes a first hard mask layer, a second hard mask layer over the first hard mask layer, and a third hard mask layer over the second hard mask layer. The method further includes forming a spacer layer having a pattern over the hard mask structure. The method further includes performing a patterning process to transfer the pattern of the spacer layer to the first hard mask layer and the second hard mask layer of the hard mask structure. The method further includes removing the second hard mask layer from the first hard mask layer after the patterning process is complete. The method further includes etching the dielectric structure through the first hard mask layer.

### BACKGROUND

### Field of Invention

The present disclosure relates to a method for manufacturing a memory device.

### Description of Related Art

As the integration density of memory devices increases, distances between features have gradually decreased in a highly miniaturized memory device. However, some issues of fabricating the memory devices may arise from the scaling down process. For example, dry etching is often applied in a typical process for forming the desired features. Nevertheless, by-products may be formed during dry etching, and deformation and pattern distortion in the etched structure may thus occur.

Accordingly, how to provide a method for manufacturing a memory device to solve the aforementioned problems becomes an important issue to be solved by those in the industry.

### SUMMARY

An aspect of the disclosure is to provide a method for manufacturing a memory device that may efficiently solve the aforementioned problems.

According to an embodiment of the disclosure, a method for manufacturing a memory device includes forming a hard mask structure over a dielectric structure. The hard mask structure includes a first hard mask layer, a second hard mask layer over the first hard mask layer, and a third hard mask layer over the second hard mask layer. The method further includes forming a spacer layer having a pattern over the hard mask structure. The method further includes performing a patterning process to transfer the pattern of the spacer layer to the first hard mask layer and the second hard mask layer of the hard mask structure. The method further includes removing the second hard mask layer from the first hard mask layer after the patterning process is complete. The method further includes etching the dielectric structure through the first hard mask layer.

In some embodiments of the present disclosure, the second hard mask layer has a higher oxygen concentration than the third hard mask layer.

In some embodiments of the present disclosure, the third hard mask layer has a higher silicon concentration than the second hard mask layer.

In some embodiments of the present disclosure, the first hard mask layer is a carbon-containing material.

In some embodiments of the present disclosure, the patterning process includes performing a first etching process to transfer the pattern of the spacer layer to the second hard mask layer, and performing a second etching process to transfer the pattern of the second hard mask layer to the first hard mask layer.

In some embodiments of the present disclosure, the spacer layer and the third hard mask layer are consumed during the first etching process.

In some embodiments of the present disclosure, during the second etching process, a top surface of the second hard mask layer is free of coverage by the spacer layer and the third hard mask layer.

In some embodiments of the present disclosure, the second hard mask layer is removed from the first hard mask layer such that a top surface of the first hard mask layer is exposed.

According to another embodiment of the disclosure, a method for manufacturing a memory device includes forming a dielectric structure over an array area and a periphery area of a substrate. The method further includes forming a hard mask structure over the dielectric structure. The hard mask structure includes a first hard mask layer, a second hard mask layer over the first hard mask layer, and a third hard mask layer over the second hard mask layer. The method further includes performing a patterning process to form a plurality of first openings in a first portion of the first hard mask layer over the array area of the substrate, while keeping a second portion of the first hard mask layer over the periphery area of the substrate substantially intact. The method further includes removing a first portion of the second hard mask layer over the array area of the substrate from the first portion of the first hard mask layer after the patterning process is complete. The method further includes etching a first portion of the dielectric structure over the array area of the substrate through the first portion of the first hard mask layer.

In some embodiments of the present disclosure, performing the patterning process includes forming a photoresist covering the periphery area of the substrate. Performing the patterning process further includes performing a first etching process to form a plurality of second openings in a first portion of the third hard mask layer over the array area of the substrate and the first portion of the second hard mask layer. A plurality of bottom ends of the second openings are higher than a bottom surface of the second hard mask layer. Performing the patterning process further includes performing a second etching process to extend the second openings in the first portion of the second hard mask layer until the first portion of the first hard mask layer is exposed. Performing the patterning process further includes performing a third etching process to form the first openings in the first portion of the first hard mask layer through the second openings of the first portion of the second hard mask layer.

In some embodiments of the present disclosure, the first portion of the third hard mask layer is removed once the second etching process is complete.

In some embodiments of the present disclosure, the method further includes removing the photoresist after performing the first etching process and prior to performing the third etching process.

In some embodiments of the present disclosure, the second etching process is performed such that a plurality of third openings are formed in a second portion of the second hard mask layer over the periphery area of the substrate, wherein a plurality of bottom ends of the third openings are higher than the bottom surface of the second hard mask layer.

In some embodiments of the present disclosure, during the third etching process, an entirety of the second portion of the first hard mask layer is covered by the second portion of the second hard mask layer.

In some embodiments of the present disclosure, removing the first portion of the second hard mask layer is performed such that a top surface of the first portion of the first hard mask layer is exposed.

In some embodiments of the present disclosure, the second hard mask layer and the third hard mask layer are made of silicon oxynitride, and the first hard mask layer is made of a carbon-containing material.

In some embodiments of the present disclosure, the second hard mask layer has a higher oxygen concentration than the third hard mask layer.

In some embodiments of the present disclosure, the third hard mask layer has a higher silicon concentration than the second hard mask layer.

In some embodiments of the present disclosure, the first hard mask layer is made of amorphous carbon.

In some embodiments of the present disclosure, the method further includes forming conductive materials in the etched dielectric structure.

Accordingly, in the method for manufacturing the memory device of some embodiments of the present disclosure, the first hard mask layer is first patterned by using the overlying second hard mask layer as an etching mask, while keeping the underlying dielectric structure substantially intact. Then, the second hard mask layer is removed from the first hard mask layer. Next, the dielectric structure is patterned by using the first hard mask layer as an etching mask. In this way, by-product layers including such as polymer generated during the etching process for removing the second hard mask layer may not be formed in contact with the etched dielectric structure. Thereby, deformation and pattern distortion of the etched dielectric structure caused by stress exerted by the by-product layers can be mitigated.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 to FIG. 6 illustrate a method in various stages of forming a memory device in accordance with some embodiments of the present disclosure; and

FIG. 7 to FIG. 15 illustrate a method in various stages of forming a semiconductor device in accordance with some other embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

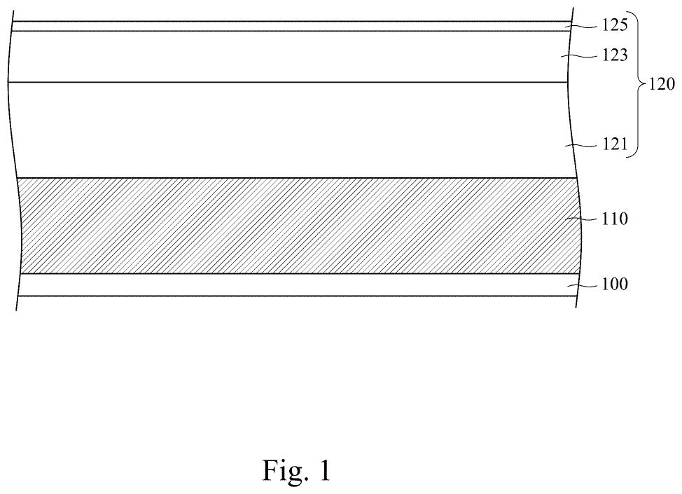

FIG. 1 to FIG. 6 illustrate a method in various stages of forming a memory device in accordance with some embodiments of the present disclosure.

Reference is made to FIG. 1. Shown there is a semiconductor substrate 100. In some embodiments, the semiconductor substrate 100 may be a silicon substrate, silicon epitaxial substrate, silicon-on-insulator (SOI) substrate, or other suitable materials of semiconductor substrate.

As shown in FIG. 1, a dielectric structure 110 is formed over the semiconductor substrate 100. In some embodiments, the dielectric structure 110 may be in direct contact with a top surface of the semiconductor substrate 100. According to some embodiments, the dielectric structure 110 may be made of oxide, such as silicon oxide (SiO₂). For example, the dielectric structure 110 may be TEOS-based CVD oxide that is deposited by using tetra-ethyl-ortho-silicate as precursor, but the present disclosure is not limited thereto. In some embodiments, the dielectric structure 110 may include a plurality of oxide layers deposited using different processes, respectively.

As shown in FIG. 1, a hard mask structure 120 is formed over the dielectric structure 110. The hard mask structure 120 includes a first hard mask layer 121, a second hard mask layer 123 over the first hard mask layer 121, and a third hard mask layer 125 over the second hard mask layer 123. In some embodiments, the first hard mask layer 121 may be in direct contact with a top surface of the dielectric structure 110. In some embodiments, the second hard mask layer 123 may be in direct contact with a top surface of the first hard mask layer 121. In some embodiments, the third hard mask layer 125 may be in direct contact with a top surface of the second hard mask layer 123. In some embodiments, plasma-enhanced chemical vapor deposition (PECVD) processes are carried out to sequentially form the first hard mask layer 121, the second hard mask layer 123, and the third hard mask layer 125 over the dielectric structure 110. According to some embodiments, the first hard mask layer 121 may be a carbon-containing material, such as amorphous carbon. In some embodiments, the second hard mask layer 123 and the third hard mask layer 125 include dielectric anti-reflective coating (DARC) material. For example, the second hard mask layer 123 and the third hard mask layer 125 may be made of a same material, such as silicon oxynitride (SiON). In some embodiments, the second hard mask layer 123 and the third hard mask layer 125 may have different silicon to oxygen (Si/O) ratios. For example, the second hard mask layer 123 may be or include an oxygen-rich silicon oxynitride layer, and the third hard mask layer 125 may be or include a silicon-rich silicon oxynitride layer. As a result, the second hard mask layer 123 has a higher oxygen concentration than the third hard mask layer 125. On the other hand, the third hard mask layer 125 has a higher silicon concentration than the second hard mask layer 123.

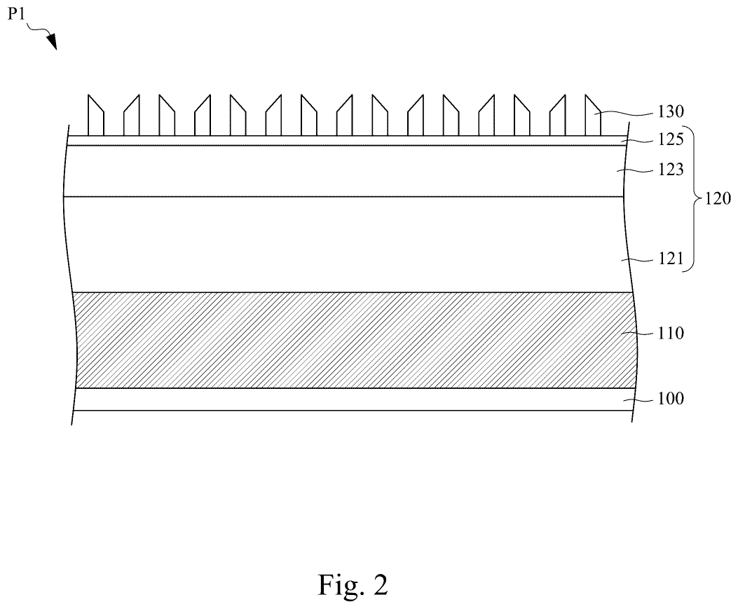

Reference is made to FIG. 2. A spacer layer 130 is formed over the hard mask structure 120. The spacer layer 130 has a pattern P1. According to some embodiments, the spacer layer 130 may be made of oxide, such as silicon oxide. In some embodiments, the spacer layer 130 may be formed by forming a photoresist having a predetermined pattern having a larger pitch than the pattern P1 on the third hard mask layer 125, forming a spacer material conformally covering the photoresist and the third hard mask layer 125, etching horizontal portions of the spacer material to expose top surfaces of the photoresist and the third hard mask layer 125, and then removing the photoresist. The remaining vertical portions of the spacer material thus form the spacer layer 130 having the pattern P1. However, the present disclosure is not limited thereto, other suitable methods may also be applied to form the spacer layer 130.

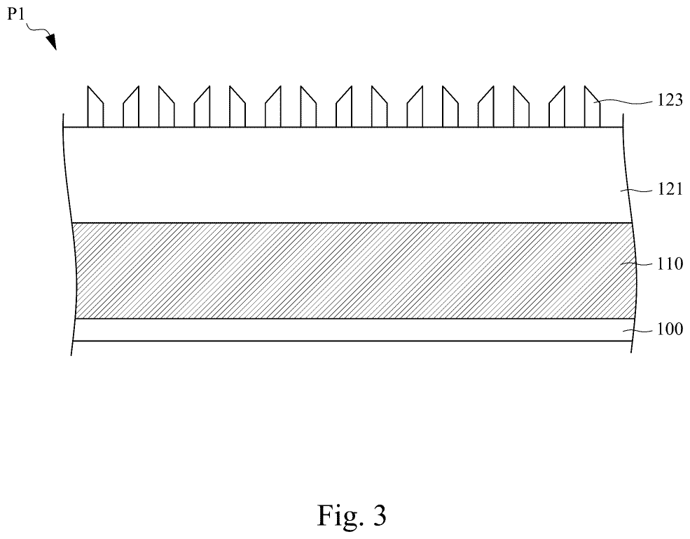

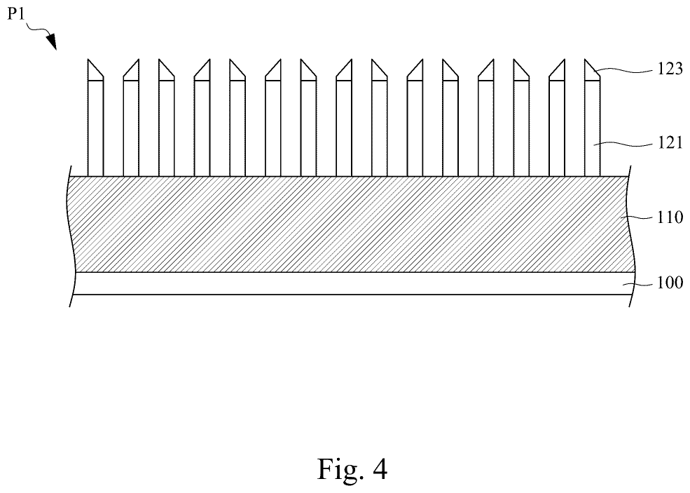

Reference is made to FIG. 3 to FIG. 4. A patterning process is performed to transfer the pattern P1 of the spacer layer 130 to the first hard mask layer 121 and the second hard mask layer 123 of the hard mask structure 120. In greater detail, the patterning process includes a first etching process and a second etching process. As shown in FIG. 3, the first etching process is performed to transfer the pattern P1 of the spacer layer 130 to the second hard mask layer 123. According to some embodiments, by using the spacer layer 130 as an etching mask, the first etching process is performed on the third hard mask layer 125 and the second hard mask layer 123 until the top surface of the first hard mask layer 121 is exposed. In some embodiments, during the first etching process, the spacer layer 130, the third hard mask layer 125, and the second hard mask layer 123 are etched at similar etching rates. Therefore, when the top surface of the first hard mask layer 121 is exposed, the spacer layer 130 and the third hard mask layer 125 are consumed. In addition, the etched second hard mask layer 123 has the pattern P1.

As shown in FIG. 4, the second etching process is performed to transfer the pattern P1 of the second hard mask layer 123 to the first hard mask layer 121. According to some embodiments, by using the second hard mask layer 123 as an etching mask, the second etching process is performed on the first hard mask layer 121 until the top surface of the dielectric structure 110 is exposed. In some embodiment, since the spacer layer 130 and the third hard mask layer 125 are consumed in the first etching process as aforementioned, the top surface of the second hard mask layer 123 is free of coverage by the spacer layer 130 and the third hard mask layer 125 during the second etching process.

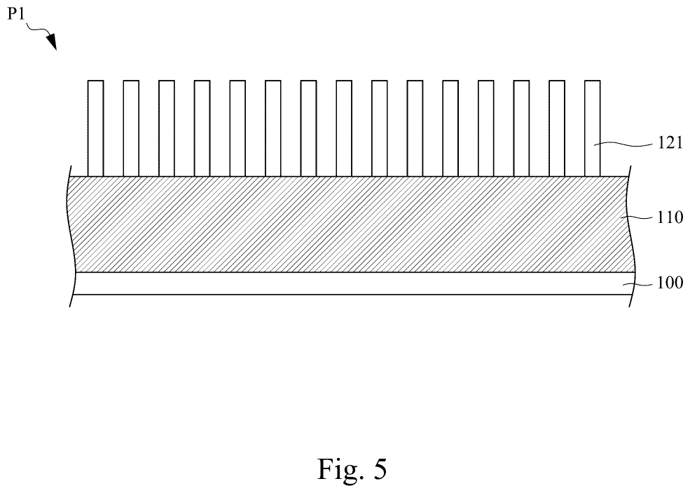

Reference is made to FIG. 5. After the patterning process is complete, the second hard mask layer 123 is removed from the first hard mask layer 121. In greater detail, the second hard mask layer 123 is removed from the first hard mask layer 121 such that the top surface of the first hard mask layer 121 is exposed. In some embodiments, the second hard mask layer 123 may be etched with high etching selectivity to the dielectric structure 110 such that the top surface of the dielectric structure 110 remains substantially intact after the removal of the second hard mask layer 123.

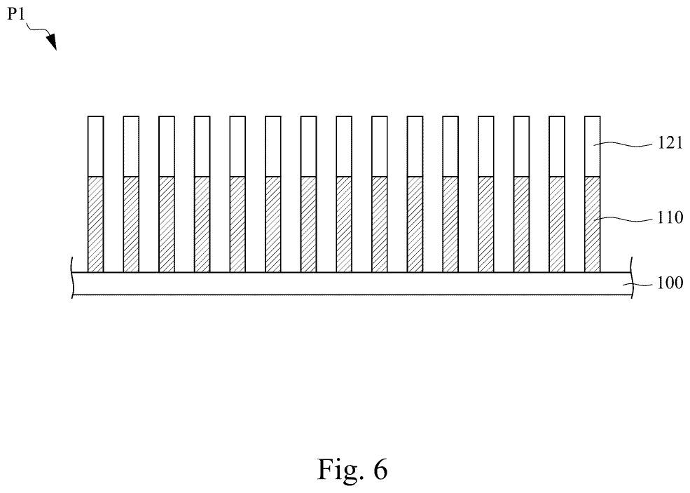

Reference is made to FIG. 6. After the second hard mask layer 123 is removed, the dielectric structure 110 is patterned by using the first hard mask layer 121 as an etching mask, so as to transfer the pattern P1 of the first hard mask layer 121 to the dielectric structure 110. After the dielectric structure 110 is etched through the first hard mask layer 121, the dielectric structure 110 has the pattern P1.

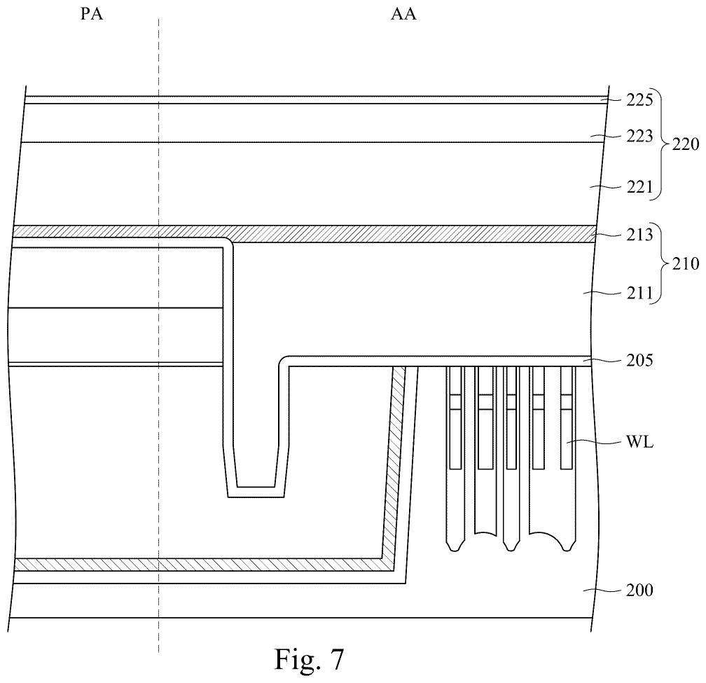

FIG. 7 to FIG. 15 illustrate a method in various stages of forming a semiconductor device in accordance with some other embodiments of the present disclosure.

Reference is made to FIG. 7. Shown there is a semiconductor substrate 200. The semiconductor substrate 200 includes an array area AA and a periphery area PA. In some embodiments, the semiconductor substrate 200 may be a silicon substrate, silicon epitaxial substrate, silicon-on-insulator (SOI) substrate, or other suitable materials of semiconductor substrate. Wordlines WL are formed in the array area AA. According to some embodiments, the wordlines WL may be buried in the array area AA. That is, top surfaces of the word lines may be level with or lower than a top surface of the semiconductor substrate 200. Source/drain regions (not shown) may be formed in an active region at both sides of the word lines WL. As such, a plurality of semiconductor devices (e.g. transistors) for the memory device may be formed in the semiconductor substrate 200. Here, the term “periphery area PA” may be a region of the semiconductor substrate 200 that is free of semiconductor devices. For example, the periphery area PA of the semiconductor substrate 200 may be free of the wordlines WL shown in the array area AA.

As shown in FIG. 7, a dielectric structure 210 is formed over the array area AA and the periphery area PA of the semiconductor substrate 200. In some embodiments, the dielectric structure 210 may include a first dielectric layer 211 and a second dielectric layer 213 over the first dielectric layer 211. According to some embodiments, the first dielectric layer 211 is disposed only over the array area AA. In some embodiments, prior to forming the dielectric structure 210, an etch stop layer 205 may be formed, which conformally covers the array area AA and the periphery area PA of the semiconductor substrate 200.

According to some embodiments, the first dielectric layer 211 and the second dielectric layer 213 may be made of oxide, such as silicon oxide. For example, the first dielectric layer 211 may be spin-on-dielectric (SOD) oxide or high-density plasma (HDP) oxide. The second dielectric layer 213 may be TEOS-based CVD oxide that is deposited by using tetra-ethyl-ortho-silicate as precursor. However, the present disclosure is not limited thereto, the dielectric structure 210 may include a combination of oxide layers formed with other suitable methods. The etch stop layer 205 may be formed of a material having an etch selectivity during etching of the dielectric structure 210. For example, the etch stop layer 205 may be formed of a silicon nitride layer or a silicon oxynitride layer.

As shown in FIG. 7, a hard mask structure 220 is formed over the dielectric structure 210 and over the array area AA and the periphery area PA of the semiconductor substrate 200. The hard mask structure 220 includes a first hard mask layer 221, a second hard mask layer 223 over the first hard mask layer 221, and a third hard mask layer 225 over the second hard mask layer 223. In some embodiments, the first hard mask layer 221 may be in direct contact with a top surface of the dielectric structure 210. In some embodiments, the second hard mask layer 223 may be in direct contact with a top surface of the first hard mask layer 221. In some embodiments, the third hard mask layer 225 may be in direct contact with a top surface of the second hard mask layer 223. In some embodiments, plasma-enhanced chemical vapor deposition processes are carried out to sequentially form the first hard mask layer 221, the second hard mask layer 223, and the third hard mask layer 225 over the dielectric structure 210.

According to some embodiments, the first hard mask layer 221 may be a carbon-containing material, such as amorphous carbon. In some embodiments, the second hard mask layer 223 and the third hard mask layer 225 may be made of dielectric anti-reflective coating material. For example, the second hard mask layer 223 and the third hard mask layer 225 may include a same material, such as silicon oxynitride. In some embodiments, the second hard mask layer 223 and the third hard mask layer 225 may have different silicon to oxygen ratios. For example, the second hard mask layer 223 may be or include an oxygen-rich silicon oxynitride layer, and the third hard mask layer 225 may be or include a silicon-rich silicon oxynitride layer. As a result, an oxygen concentration of the second hard mask layer 223 is higher than an oxygen concentration of the third hard mask layer 225. On the other hand, a silicon concentration of the third hard mask layer 225 is higher than a silicon concentration of the second hard mask layer 223.

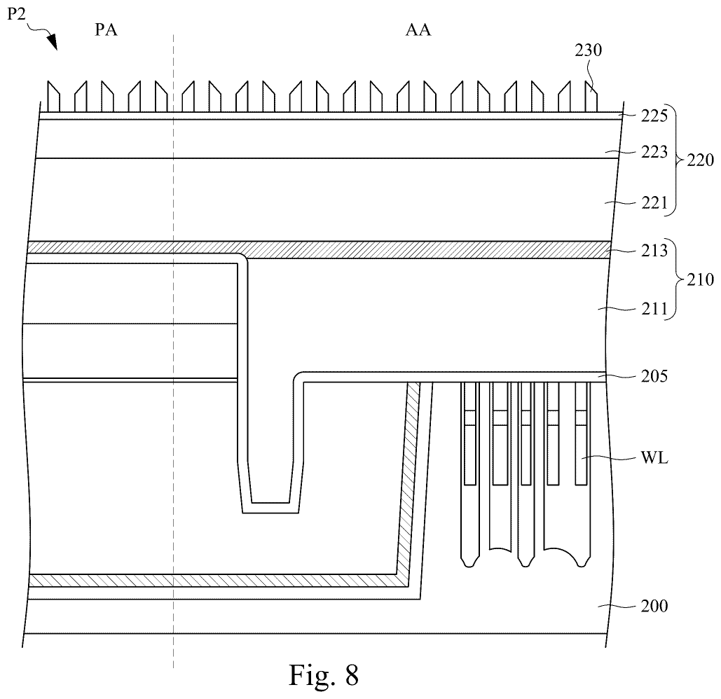

Reference is made to FIG. 8. A spacer layer 230 is formed over the hard mask structure 220. The spacer layer 230 has a pattern P2. According to some embodiments, the spacer layer 230 may be made of oxide, such as silicon oxide. In some embodiments, the spacer layer 230 may be formed by applying similar methods for forming the spacer layer 130.

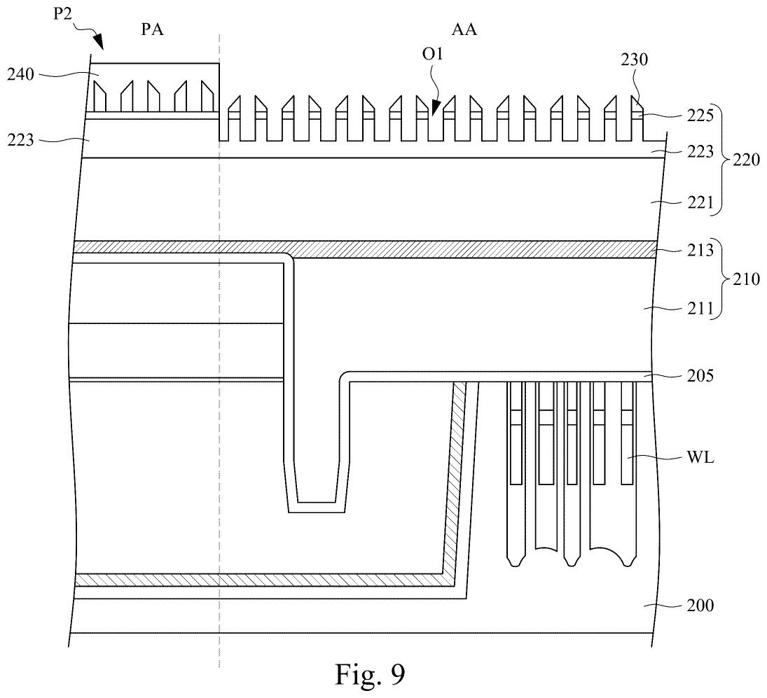

Reference is made to FIG. 9 to FIG. 12. A patterning process is performed to form openings in a first portion of the first hard mask layer 221 over the array area AA of the semiconductor substrate 200. As a result, once the patterning process is complete, the pattern P2 of the spacer layer 230 is transferred to the first portion of the first hard mask layer 221. According to some embodiments, the patterning process includes a first etching process, a second etching process, and a third etching process. Besides, during the patterning process, a second portion of the first hard mask layer 221 over the periphery area PA of the semiconductor substrate 200 is kept substantially intact.

As shown in FIG. 9, the first etching process of the patterning process is performed to form openings O1 in a first portion of the third hard mask layer 225 and a first portion of the second hard mask layer 223 over the array area AA of the semiconductor substrate 200. To be more specific, the openings O1 are formed by using a first portion of the spacer layer 230 over the array area AA of the semiconductor substrate 200 as an etching mask. The openings O1 extend through the first portion of the third hard mask layer 225. In some embodiments, bottom ends of the openings O1 are higher than a bottom surface of the second hard mask layer 223. In other words, after the first etching process is complete, the openings O1 does not extend through the first portion of the second hard mask layer 223.

In some embodiments, prior to performing the first etching process, a photoresist 240 is formed covering the periphery area PA of the semiconductor substrate 200. For example, as shown in FIG. 9, the photoresist 240 is over second portions of the third hard mask layer 225 and the spacer layer 230 over the periphery area PA of the semiconductor substrate 200. As such, during the second etching process, the hard mask structure 220 and the spacer layer 230 over the periphery area PA, which are protected by the photoresist 240, are kept substantially intact.

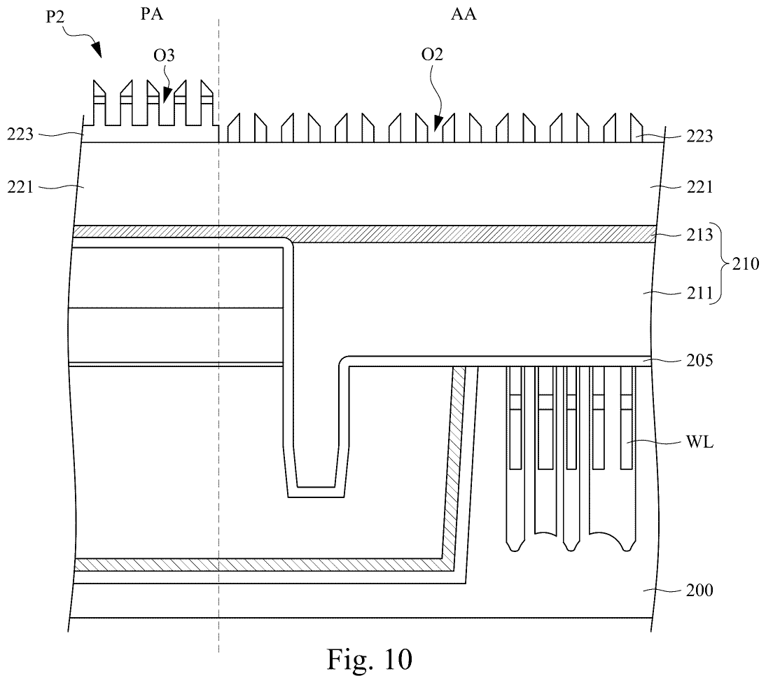

As shown in FIG. 10, the second etching process is performed to extend the openings O1 in the first portion of the second hard mask layer 223 until the first portion of the first hard mask layer 221 is exposed. As a result, openings O2 extending through the first portion of the second hard mask layer 223 are formed, thereby transferring the pattern P2 to the first portion of the second hard mask layer 223. In some embodiments, during the second etching process, the first portions of the spacer layer 230, the third hard mask layer 225, and the second hard mask layer 223 are etched at similar etching rates. Therefore, the first portions of the spacer layer 230 and the third hard mask layer 225 are removed once the second etching process is complete. That is, once the second etching process is complete, the top surface of the first portion of the third hard mask layer 225 may be exposed.

In addition, the photoresist 240 may be removed after performing the first etching process and prior to performing the third etching process. For example, the photoresist 240 is removed after the first etching process and prior to the second etching process. Consequently, after performing the second etching, openings O3 are formed in a second portion of the second hard mask layer 223 over the periphery area PA of the semiconductor substrate 200. Similarly, the openings O3 are formed by using the spacer layer 230 as an etching mask. The openings O3 extend through the second portion of the third hard mask layer 225. According to some embodiments, bottom ends of the openings O3 are higher than the bottom surface of the second hard mask layer 223. In other words, the openings O3 does not extend through the second portion of the second hard mask layer 223.

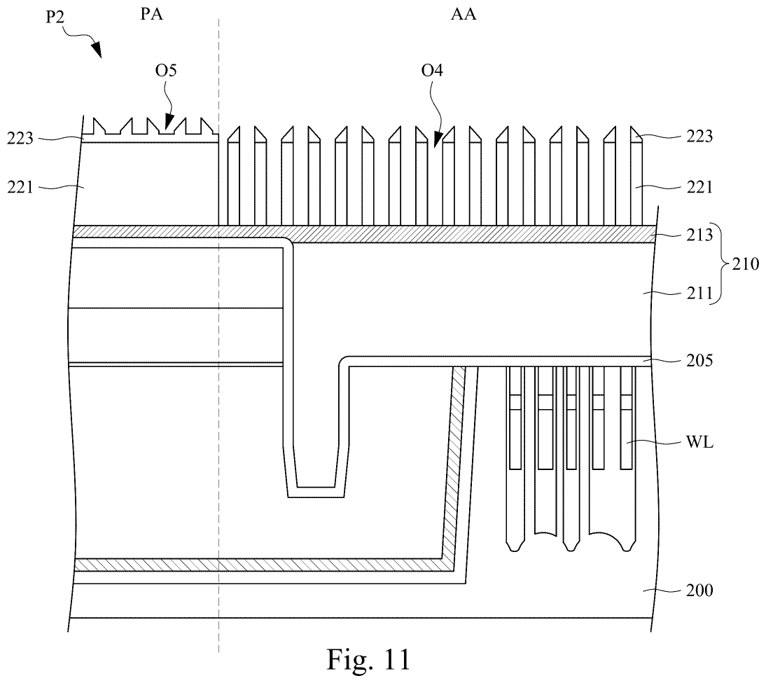

As shown in FIG. 11, the third etching process is performed to form openings O4 in the first portion of the first hard mask layer 221 through the openings O2 of the first portion of the second hard mask layer 223. After the third etching process, the top surface of the dielectric structure 210 is exposed through the openings O4. The pattern P2 is thus transferred to the first portion of the first hard mask layer 221.

In some embodiments, the third etching process further extends the openings O3 in the second portion of the second hard mask layer 223, thus forming openings O5. According to some embodiments, bottom ends of the openings O5 may be higher than the bottom surface of the second hard mask layer 223. As a result, an entirety of the second portion of the first hard mask layer 221 is covered by the second portion of the second hard mask layer 223 during the third etching process. Hence, the second portion of the first hard mask layer 221 is kept substantially intact.

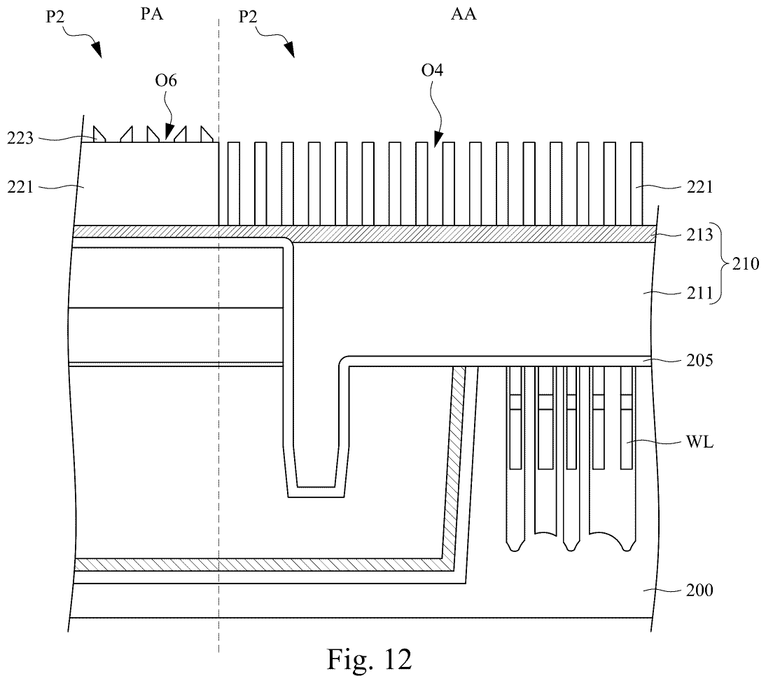

Reference is made to FIG. 12. After the patterning process is complete, the first portion of the second hard mask layer 223 is removed from the first portion of the first hard mask layer 221. To be more specific, the first portion of the second hard mask layer 223 is removed such that the top surface of the first portion of the first hard mask layer 221 is exposed. In some embodiments, during the removal of the first portion of the second hard mask layer 223, the openings O5 is extended in the second portion of the second hard mask layer 223, thus forming openings O6 that expose the top surface of the second portion of the first hard mask layer 221. In some embodiments, the first portion of the second hard mask layer 223 may be completely removed from the array area AA, while the second portion of the second hard mask layer 223 may remain over the periphery area PA.

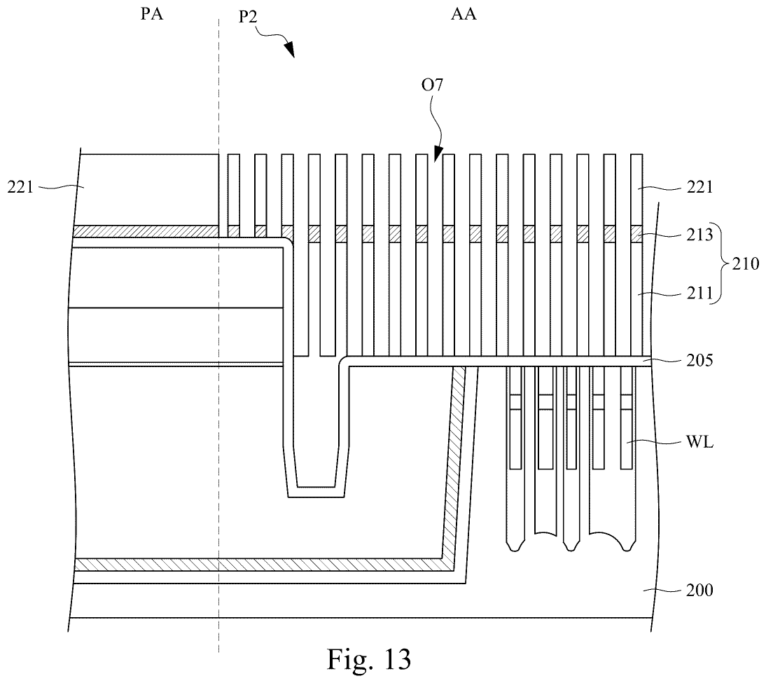

Reference is made to FIG. 13. Once the first portion of the second hard mask layer 223 is removed, a first portion of the dielectric structure 210 over the array area AA of the semiconductor substrate 200 is patterned by using the first portion of the first hard mask layer 221 as an etching mask, so as to transfer the pattern P2 of the first portion of the first hard mask layer 121 to the first portion of the dielectric structure 110. As such, openings O7 are formed extending through the second dielectric layer 213 and the first dielectric layer 211 of the dielectric structure 210. In addition, the first portion of the dielectric structure 210 is etched until a portion of the etch stop layer 205 over the wordlines WL is exposed by the openings O7.

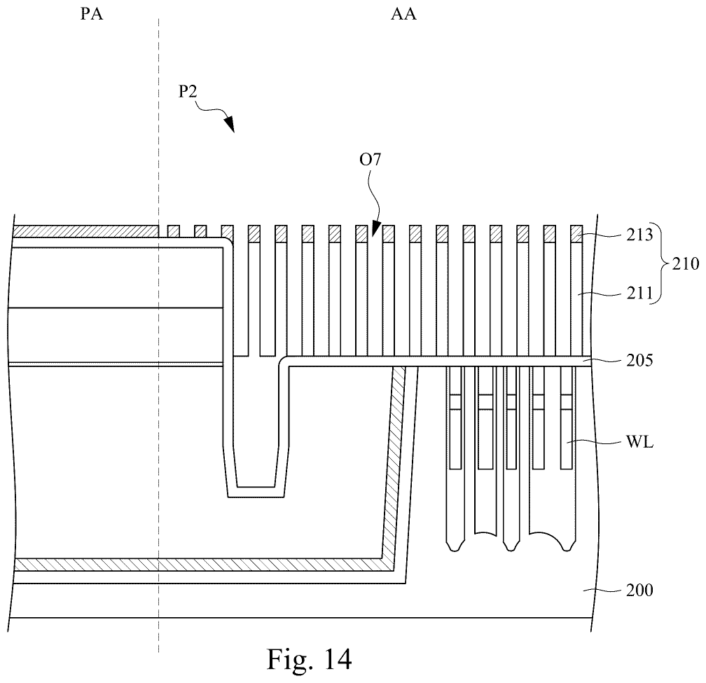

Reference is made to FIG. 14. The first portion and the second portion of the first hard mask layer 221 are removed from the dielectric structure 210. To be more specific, the first hard mask layer 221 is removed such that the top surface of the second dielectric layer 213 is exposed.

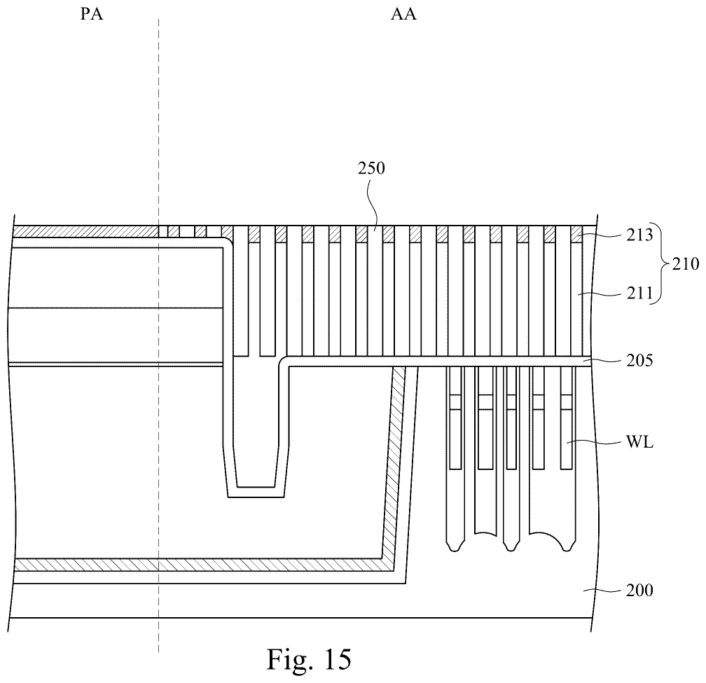

Reference is made to FIG. 15. A conductive layer 250 is formed in the etched dielectric structure 210. In greater detail, the conductive layer 250 is formed by overfilling conductive materials in the openings O7 in the etched dielectric structure 210 and then planarizing the conductive materials to expose the top surface of the second dielectric layer 213. In some embodiments, the conductive layer 250 may include polysilicon doped with impurities, metal, metal nitride, and/or metal silicide.

Accordingly, in the method for manufacturing the memory device of some embodiments of the present disclosure, the first hard mask layer is first patterned by using the overlying second hard mask layer as an etching mask, while keeping the underlying dielectric structure substantially intact. Then, the second hard mask layer is removed from the first hard mask layer. Next, the dielectric structure is patterned by using the first hard mask layer as an etching mask. In this way, by-product layers including such as polymer generated during the etching process for removing the second hard mask layer may not be formed in contact with the etched dielectric structure. Thereby, deformation and pattern distortion of the etched dielectric structure caused by stress exerted by the by-product layers can be mitigated.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A method for manufacturing a memory device, comprising:
forming a hard mask structure over a dielectric structure, wherein the hard mask structure comprises a first hard mask layer, a second hard mask layer over the first hard mask layer, and a third hard mask layer over the second hard mask layer;
forming a spacer layer having a pattern over the hard mask structure;
performing a patterning process to transfer the pattern of the spacer layer to the first hard mask layer and the second hard mask layer of the hard mask structure;
after the patterning process is complete, removing the second hard mask layer from the first hard mask layer; and
etching the dielectric structure through the first hard mask layer.

2. The method of claim 1, wherein the second hard mask layer has a higher oxygen concentration than the third hard mask layer.

3. The method of claim 1, wherein the third hard mask layer has a higher silicon concentration than the second hard mask layer.

4. The method of claim 1, wherein the first hard mask layer is a carbon-containing material.

5. The method of claim 1, wherein the patterning process comprises:
performing a first etching process to transfer the pattern of the spacer layer to the second hard mask layer; and
performing a second etching process to transfer the pattern of the second hard mask layer to the first hard mask layer.

6. The method of claim 5, wherein the spacer layer and the third hard mask layer are consumed during the first etching process.

7. The method of claim 6, wherein during the second etching process, a top surface of the second hard mask layer is free of coverage by the spacer layer and the third hard mask layer.

8. The method of claim 1, wherein the second hard mask layer is removed from the first hard mask layer such that a top surface of the first hard mask layer is exposed.

9. A method for manufacturing a memory device, comprising:
forming a dielectric structure over an array area and a periphery area of a substrate;
forming a hard mask structure over the dielectric structure, wherein the hard mask structure comprises a first hard mask layer, a second hard mask layer over the first hard mask layer, and a third hard mask layer over the second hard mask layer;
performing a patterning process to form a plurality of first openings in a first portion of the first hard mask layer over the array area of the substrate, while keeping a second portion of the first hard mask layer over the periphery area of the substrate substantially intact;
after the patterning process is complete, removing a first portion of the second hard mask layer over the array area of the substrate from the first portion of the first hard mask layer; and
etching a first portion of the dielectric structure over the array area of the substrate through the first portion of the first hard mask layer.

10. The method of claim 9, wherein performing the patterning process comprises:
forming a photoresist covering the periphery area of the substrate;
performing a first etching process to form a plurality of second openings in a first portion of the third hard mask layer over the array area of the substrate and the first portion of the second hard mask layer, wherein a plurality of bottom ends of the second openings are higher than a bottom surface of the second hard mask layer;
performing a second etching process to extend the second openings in the first portion of the second hard mask layer until the first portion of the first hard mask layer is exposed; and
performing a third etching process to form the first openings in the first portion of the first hard mask layer through the second openings of the first portion of the second hard mask layer.

11. The method of claim 10, wherein the first portion of the third hard mask layer is removed once the second etching process is complete.

12. The method of claim 10, further comprising removing the photoresist after performing the first etching process and prior to performing the third etching process.

13. The method of claim 12, wherein the second etching process is performed such that a plurality of third openings are formed in a second portion of the second hard mask layer over the periphery area of the substrate, wherein a plurality of bottom ends of the third openings are higher than the bottom surface of the second hard mask layer.

14. The method of claim 13, wherein during the third etching process, an entirety of the second portion of the first hard mask layer is covered by the second portion of the second hard mask layer.

15. The method of claim 9, wherein removing the first portion of the second hard mask layer is performed such that a top surface of the first portion of the first hard mask layer is exposed.

16. The method of claim 9, wherein the second hard mask layer and the third hard mask layer are made of silicon oxynitride, and the first hard mask layer is made of a carbon-containing material.

17. The method of claim 16, wherein the second hard mask layer has a higher oxygen concentration than the third hard mask layer.

18. The method of claim 16, wherein the third hard mask layer has a higher silicon concentration than the second hard mask layer.

19. The method of claim 16, wherein the first hard mask layer is made of amorphous carbon.

20. The method of claim 9, further comprising forming conductive materials in the etched dielectric structure.
